(19) United States
(12) Patent Application Publication
(10) Pub. No.: US 2025/0277828 A1
(43) Pub. Date: Sep. 4, 2025

(54) CURRENT SENSOR CIRCUIT WITH DIFFERENCE AMPLIFIER

(71) Applicant: TEXAS INSTRUMENTS INCORPORATED, Dallas, TX (US)

(72) Inventors: Sourodeep BASU, Bangalore (IN); Dipankar MANDAL, Bangalore (IN)

(21) Appl. No.: 18/591,877

(22) Filed: Feb. 29, 2024

(51) Int. Cl. G01R 19/25; H03F 3/45

(52) U.S. Cl. CPC G01R 19/25; H03F 3/45475

(57) ABSTRACT

A current sensor circuit includes a sensing resistor having a first node adapted to be coupled to a high side terminal of a voltage supply and a second node adapted to be coupled to a high side terminal of a DUT (device under test). A low side terminal of the DUT is coupled to a first ground node. The current sensor circuit includes a difference amplifier coupled to the first node and the second node of the sensing resistor. A low side power terminal of the difference amplifier is coupled to a second ground node, and the second ground node is coupled to the high side terminal of the DUT. The current sensor circuit also includes an isolation DC (direct current)-to-DC converter having an output coupled to a high side power terminal of the difference amplifier.

### TECHNICAL FIELD

This description relates to a circuit for sensing current that includes a difference amplifier.

### BACKGROUND

A difference amplifier, also known as a differential amplifier, is an electronic device that amplifies the difference between two input voltages while rejecting voltage that is common to both inputs (common mode voltage). Difference amplifiers are employed in situations where a signal of interest is the voltage difference between two points, which may be superimposed on the common-mode voltage that is not of interest and should be curtailed.

An operational amplifier, commonly known as an op-amp, is a type of voltage amplifier that is designed to amplify the difference between two input voltage levels. Op-amps typically has a very high gain and are used in a variety of configurations depending on the application.

Placing a sensing resistor in series with a circuit under test offers a straightforward method for measuring current, leveraging the fundamental principle of Ohm's Law. In this setup, the sensing resistor is inserted directly into a current path of the circuit under test. As current flows through this sensing resistor, a voltage drop across the sensing resistor is directly proportional to the amount of current across the resistor and to the current provided to the circuit under test due to the relationship defined by Ohm's Law (V=IR, where V is the voltage across the resistor, I is the current through the resistor, and R is the resistance). By measuring this voltage drop and knowing the resistance of the sensing resistor, the current flowing through the circuit can be accurately calculated.

### SUMMARY

A first example relates to a current sensor circuit that includes a sensing resistor having a first node adapted to be coupled to a high side terminal of a voltage supply and a second node adapted to be coupled to a high side terminal of a DUT (device under test). A low side terminal of the DUT is coupled to a first ground node. The current sensor circuit includes a difference amplifier coupled to the first node and the second node of the sensing resistor. A low side power terminal of the difference amplifier is coupled to a second ground node, and the second ground node is coupled to the high side terminal of the DUT. The current sensor circuit also includes an isolation DC (direct current)-to-DC converter having an output coupled to a high side power terminal of the difference amplifier.

A second example relates to a current sensing circuit that includes a sensing resistor having a first node adapted to be coupled to a high side terminal of a voltage supply and a second node adapted to be coupled to a high side terminal of a DUT. A low side terminal of the DUT is coupled to a first ground node. The current sensing circuit includes a difference amplifier coupled to the first node and the second node of the sensing resistor. A low side power terminal of the difference amplifier is coupled to a second ground node that is galvanically isolated from the first ground node, and the second ground node is coupled to the high side terminal of the DUT. The difference amplifier is configured to output a sensed voltage that varies as a function of a current across the sensing resistor. The current sensing circuit also includes an isolation DC-to-DC converter configured to provide an isolated voltage to a high side power terminal of the difference amplifier.

A third example relates to a method for sensing current. The method includes sensing, by a difference amplifier, a voltage drop across a sensing resistor having a first node adapted to be coupled to a high side terminal of a voltage supply and a second node adapted to be coupled to a high side terminal of a DUT. A low side terminal of the DUT is coupled to a first ground node, the difference amplifier is coupled to the first node and the second node of the sensing resistor and a low side power terminal of the difference amplifier is coupled to a second ground node. The second ground node is coupled to the high side terminal of the DUT. The method also includes outputting, by the difference amplifier, a sensed voltage that varies as a function of a current across the sensing resistor in response to receiving an isolated voltage at a high side power terminal of the difference amplifier provided from an isolation DC (direct current)-to-DC converter.

### BRIEF DESCRIPTION OF THE DRAWINGS

FIG. 1 illustrates an example of a current sensor circuit for sensing current provided to a DUT (device under test).

FIG. 2 illustrates an example of a circuit that includes a current sensor circuit that measures a current provided to a DUT based on a voltage provided by a high voltage supply.

FIG. 3 illustrates an IC (integrated circuit) package level circuit that is employable to implement the circuit of FIG. 2.

FIG. 4 illustrates a chart with measured results from implemented circuits.

FIG. 5 is a flowchart of an example method of sensing a current.

### DETAILED DESCRIPTION

This description relates to a circuit for measuring current that measures a voltage drop across a sensing resistor connected to a DUT (device under test). Conventional methods for measuring current encounter significant challenges when the common mode voltage between resistor terminals is high, particularly in applications exceeding 400 volts (V). Standard circuit components, such as transistors and op-amps (operational amplifiers) are not designed to handle such high common mode voltages.

This description provides a current sensor circuit capable of accurately measuring current for nearly any voltage, including high voltage applications, potentially up to and exceeding 2000 volts. The current sensor circuit employs an isolated power supply for a difference amplifier implemented with an op-amp, which allows the op-amp to operate without exposure to high common mode voltages. The current sensor circuit has separate ground references for the DUT and for the difference amplifier, effectively isolating the difference amplifier component from a high common mode voltage.

The current sensor circuit includes a sensing resistor, the difference amplifier, and an isolation DC (direct current)-to-DC converter. The sensing resistor is in series with the DUT (device under test), and the difference amplifier is configured to measure the voltage drop across this resistor. The isolation DC-to-DC converter provides an isolated voltage to a high side power terminal of the difference amplifier, ensuring that the difference amplifier operates within common mode voltage limits.

Additionally, in some examples, the current sensor circuit includes an isolation ADC (analog-to-digital converter) to digitize the sensed voltage, allowing for digital processing and readout. In some examples, the isolation ADC and the difference amplifier are implemented on a first IC (integrated circuit) package, and the isolation DC-to-DC converter can be implemented on a second IC package, further enhancing isolation between the high voltage and low voltage sides of the circuit. The current sensor circuit measures current at high voltages without the limitations of conventional approaches making this approach suitable for applications such as, high voltage electric vehicles and other high voltage systems where accurate current measurement is needed.

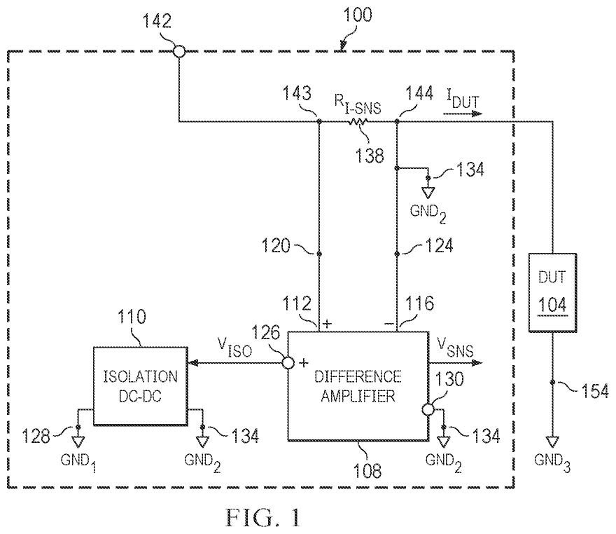

FIG. 1 illustrates an example of a current sensor circuit 100 for sensing current provided to a DUT 104. The DUT 104 represents a load that has an on-state and an off-state. For simplification, it is presumed that in the on-state, a DUT current, I_{DUT} provided to the DUT 104 is at a maximum level. Conversely, in an off-state, the DUT current, I_{DUT} provided to the DUT 104 defines a leakage current, I_{LEAK} for the DUT 104. In general, the leakage current, should be curtailed. However, for high voltage applications, it can be difficult to accurately measure the leakage current, I_{LEAK} for the DUT 104 due to a high common mode voltage, V_{CM} of conventional current measurement devices. However, the current sensor circuit 100 is configured to ensure that the common mode voltage, V_{CM} is about 5 volts (V) or less, such that standard, and precise circuit components are employable to measure the DUT current, I_{DUT} provided to the DUT 104 in both the on-state and the off-state.

The current sensor circuit 100 includes a difference amplifier 108 and an isolation DC-to-DC converter 110 (labeled ISO DC-DC). In some examples, the difference amplifier 108 is implemented with an op-amp configured as a differential amplifier for difference amplification. The difference amplifier 108 includes a non-inverting input 112 (e.g., a first input) and an inverting input 116 (e.g., a second input). The non-inverting input 112 is coupled to a first node 120 and the inverting input 116 is coupled to a second node 124. A high side power terminal 126 of the difference amplifier 108 is coupled to an output of the isolation DC-to-DC converter 110. The isolation DC-to-DC converter 110 is also coupled to a first ground node 128, GND₁. A low side power terminal 130 of the difference amplifier 108 is coupled to a second ground node 134, GND₂. The inverting input 116 of the difference amplifier 108 and the isolation DC-to-DC converter 110 are also coupled to the second ground node 134. The first ground node 128 and the second ground node 134 are galvanically isolated from each other.

The current sensor circuit 100 includes a sensing resistor 138, R_{I-SNS}. The sensing resistor 138 has a relatively small resistance, such as about 10 milliohms (mΩ) or less. The sensing resistor 138 is coupled to the first node 120 and the second node 124. Additionally, a high side terminal of the DUT 104 is coupled to the second node 124. The second node 124 is adapted to be coupled to a high side terminal 142 (e.g., an output terminal) of a voltage supply (not shown), such that the sensing resistor 138 is adapted to be coupled to the high side terminal 142 of the voltage supply. More particularly, the sensing resistor 138 has a first node 143 coupled to the first node 120, and the first node 143 is adapted to be coupled to the high side terminal 142. The sensing resistor 138 also has a second node 144 coupled to the second node 124, and the second node 144 is adapted to be coupled to the high side terminal of the DUT 104. In this manner, due to the high input impedance of the non-inverting input 112 and the inverting input 116 of the difference amplifier 108, the sensing resistor 138 is in series with the DUT 104.

A low side terminal of the DUT 104 is coupled to a third ground node 154, GND₃. The third ground node 154 is galvanically isolated from the second ground node 134 and the first ground node 128. Moreover, as illustrated, the high side terminal of the DUT 104 is coupled to the second ground node 134 (as well as the second node 124).

In operation, the voltage supply outputs a voltage on the high side terminal 142. Additionally, the isolation DC-to-DC converter 110 outputs an isolation voltage, V_{SIO} to the high side power terminal 126 of the difference amplifier 108. The voltage provided at the high side terminal 142 can be nearly any voltage. In particular, the voltage at the high side terminal 142 is a DC voltage and can be a high voltage of about 400 volts (V) to about 2000 V (or even exceeding 2000 V in some examples). The voltage at the high side terminal 142 induces a DUT current, I_{DUT}. The difference amplifier 108 is configured to measure a voltage drop across the sensing resistor 138 and output a sensing voltage, V_{SNS} that varies as a function of a current across the sensing resistor 138, which corresponds to the DUT current, I_{DUT}.

As noted, the DUT current, I_{DUT} flows to the third ground node 154. Additionally, because the inverting input 116 is coupled to the second ground node 134, and the second ground node 134 and the third ground node 154 are separate grounds (galvanically isolated), the common mode voltage between the non-inverting input 112 and the inverting input 116 is about 5 V or less with respect to the difference amplifier 108 and the second ground node 134, such that standard components, such as an op-amp is employable to implement the difference amplifier 108.

By use of the current sensor circuit 100, the DUT current, I_{DUT} is accurately measured, particularly for voltages of 400 V or more without requiring high voltage components for the difference amplifier 108. Moreover, the current sensor circuit 100 measures both on and off-state leakage current provided to the DUT 104.

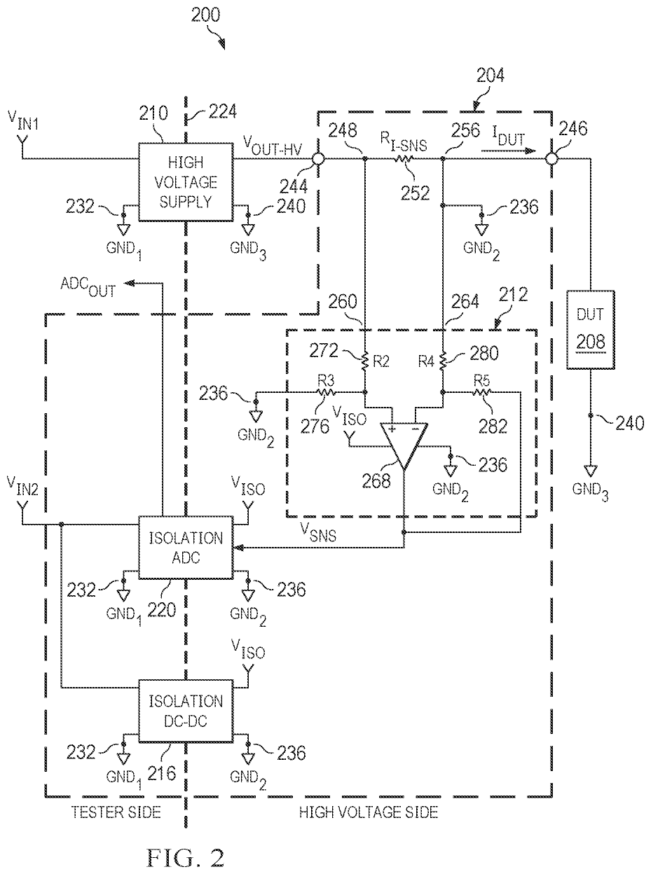

FIG. 2 illustrates an example of a circuit 200 that includes a current sensor circuit 204 that measures a current provided to a DUT 208 based on a voltage provided by a high voltage supply 210. The DUT 208 can be representative of a load, such as a test circuit or test IC package that is driven by the high voltage supply 210. The DUT 208 has an on-state and an off-state. For simplification, it is presumed that in the on-state, a DUT current, I_{DUT} provided to the DUT 208 is at a maximum level. Conversely, in an off-state, the DUT current, I_{DUT} provided to the DUT 208 defines a leakage current, I_{LEAK} for the DUT 208. In general, the leakage current, should be curtailed. However, for high voltage applications, it can be difficult to accurately measure the leakage current, I_{LEAK} for the DUT 208 due to a high common mode voltage, V_{CM} of conventional current measurement devices. However, the current sensor circuit 204 is configured to ensure that the common mode voltage, V_{CM} is about 5 volts (V) or less with respect to components of the current sensor circuit 204, such that standard, and precise circuit components are employable to measure the DUT current, I_{DUT} provided to the DUT 208 in both the on-state and the off-state.

The current sensor circuit 204 is employable to implement the current sensor circuit 100 of FIG. 1. The current sensor circuit 204 includes a difference amplifier 212 that is employable to implement the difference amplifier 108 of FIG. 1. The current sensor circuit 204 also includes an isolation DC-to-DC converter 216 (labeled ISO DC-DC) that is employable to implement the isolation DC-to-DC converter 110 of FIG. 1. The current sensor circuit 204 also includes an isolation ADC 220 (analog to digital converter, labeled ISO ADC).

The current sensor circuit 100 includes a dashed line 224 to denote a tester side and a high voltage side. In the example illustrated, voltages input and output on the tester side are less than about 20 V. Additionally, the voltages input and output on the high voltage side can be any voltage, including high voltages of at least about 400 V or greater (including 2000 V or more). Some components, such as the isolation DC-to-DC converter 216, the isolation ADC 220 and the high voltage supply 210 provide an interface between the tester side and the high voltage side.

The isolation DC-to-DC converter 216 is coupled to a first ground node 232, GND₁ and a second ground node 236, GND₂. In some examples, the high voltage supply 210 is coupled to the first ground node 232 and a third ground node 240 GND₃. In other examples, the high voltage supply 210 is not coupled to the first ground node 232 and is coupled to the third ground node 240 (e.g., the high voltage supply 210 is not an isolated voltage supply). The first ground node 232 and the second ground node 236 and the third ground node 240 are galvanically isolated from each other.

The high voltage supply 210 is coupled to a first input voltage, V_{IN1} provided from a DC supply (not shown). In some examples, the first input voltage, V_{IN1} is about 12 V or less. The isolation DC-to-DC converter 216 and the isolation ADC 220 are coupled to a second input voltage, V_{IN2} provided from a DC supply (not shown). The second input voltage, V_{IN2} is about 3 V to about 12 (e.g., about 5 V, in some examples). The isolation DC-to-DC converter 216 outputs an isolation voltage, V_{ISO} that is about 5 V above the second ground node 236, such that the isolation voltage, V_{ISO} is output with respect to the second ground node 236. The isolation voltage, V_{ISO} is output to the difference amplifier 212 and the isolation ADC 220.

The high voltage supply 210 outputs a high voltage output (V_{OUT-HV}) to a high side terminal 244 of the current sensor circuit 204. The high side terminal 244 of the current sensor circuit 204 is coupled to a first node 248 of the current sensor circuit 204. The first node 248 of the current sensor circuit 204 is coupled to a sensing resistor 252, R_{I-SNS}. The sensing resistor 252 has a resistance of about 10 mΩ or less. The sensing resistor 252 is also coupled to a second node 256 of the current sensor circuit 204. The second node 256 is coupled to the second ground node 236 through a low side terminal 246 of the current sensor circuit 204 and to a high side terminal of the DUT 208. A low side terminal of the DUT 208 is coupled to the third ground node 240.

The difference amplifier 212 has a first input 260 (e.g., a non-inverting input) coupled to the first node 248 and a second input 264 (e.g., an inverting input) coupled to the second node 256. The first input 260 is employable to implement the non-inverting input 112 of the difference amplifier 108 of FIG. 1. Similarly, the second input 264 is employable to implement the inverting input 116 of the difference amplifier 108 of FIG. 1. The difference amplifier 212 is implemented with an op-amp 268 arranged in a differential configuration. A high side power terminal of the op-amp 268 receives the isolation voltage, V_{ISO} from the isolation DC-to-DC converter 216. A low side power terminal of the op-amp 268 is coupled to the second ground node 236. Due to the high input impedance of the non-inverting input and the inverting input of the op-amp 268, the sensing resistor 252 is in series with the DUT 208.

The first input 260 of the difference amplifier 212 is coupled to a second resistor 272, R2. The second resistor 272 is also coupled to a non-inverting input of the op-amp 268. The non-inverting input of the op-amp 268 is also coupled to a third resistor 276, R3. The third resistor 276 is also coupled to the second ground node 236, GND₂. The second resistor 272 and the third resistor 276 have a resistance of about 1 kiloohm (kΩ).

The second input 264 of the difference amplifier 212 is coupled to a fourth resistor 280, R4 and to the second ground node 236. The fourth resistor 280 is also coupled to an inverting input of the op-amp 268, and to a fifth resistor 282, R5. The fifth resistor 282 is also coupled to an output of the op-amp 268, such that the fifth resistor 282 is a feedback resistor for the op-amp 268. The fourth resistor 280 and the fifth resistor 282 have a resistance of about 1 kΩ. That is, the second resistor 272, the third resistor 276, the fourth resistor 280 and the fifth resistor 282 have the same resistance.

In operation, the high voltage supply 210 outputs a high voltage output, V_{OUT-HV} on the high side terminal 244 of the current sensor circuit 204. The V_{OUT-HV} is a DC voltage. The high voltage output, V_{OUT-HV} is a voltage that is greater than about 400 V. In some examples, the V_{OUT-HV} is about 2000 V or more. This high voltage output, V_{OUT-HV} induces a DUT current, I_{DUT} that is provided to the DUT 208. The difference amplifier 212 is configured to measure a voltage drop across the sensing resistor 252, which corresponds to the DUT current, I_{DUT} and output a sensed voltage, V_{SNS} that varies as a function of a current across the sensing resistor 252 and corresponds to the DUT current, I_{DUT}. The isolation ADC 220 receives the sensed voltage, V_{SNS} and outputs a value encoded on a digital signal, ADC_{OUT} on the tester side that characterizes the voltage of the sensed voltage, V_{SNS}. The digital signal, ADC_{OUT} is provided to an external system.

Because the op-amp 268 is provided power by the isolation voltage, V_{ISO} output by the isolation DC-to-DC converter 216, the op-amp 26 is floating with respect to the ground point of the DUT 208, namely, the third ground node 240. This indicates that the ground point of the op-amp 268, namely the second ground node 236 is not directly connected to the ground reference (the third ground node 240) of the DUT 208. Instead, the op-amp 268 operates with an independent or isolated ground reference, the second ground node 236 which can be at a different electrical potential than the third ground node 240. This configuration enables the op-amp 268 to function properly in environments with high common mode voltages, as it prevents the high voltage present at the DUT 208 from impacting operation of the op-amp 268.

More particularly, as demonstrated by the current sensor circuit 100, the sensing resistor 252 is coupled to the second node 256 of the current sensor circuit 204, which is coupled to the high side terminal of the DUT 208 and to the second ground node 236. Stated differently, a DUT side of the sensing resistor 252 is shorted to the second ground node 236, GND₂.

The current sensor circuit 204 is configured such that with respect to the third ground node 240, the voltage at the first node 248 of the current sensor circuit 204 HV_{CURRENT}_{_{SNS(+)}} is equal to V_{OUT-HV} and the voltage at the second node 256 of the current sensor circuit 204 HV_{CURRENT}_{_{SNS(−)}} is determined with Equation 1:

$${HV}_{{CURRENT}_{SNS} ( - )} = {V}_{OUT - HV} - {I}_{LEAK} * {R}_{I - SNS} \qquad Equation 1$$

Wherein:
R_{I-SNS} is the resistance of the sensing resistor (e.g., about 10 mΩ in some examples).
I_{LEAK} is the leakage current of the DUT that defines the current to the DUT during intervals of time that the DUT is an off-state.

Thus, with respect to the third ground node 240, a difference voltage across the sensing resistor 252, V_{DIFF-GND3} is defined by Equation 2 and a common mode voltage, V_{CM-GND3} is defined with Equation 3.

$${V}_{DIFF - GND 3} = {I}_{LEAK} * {R}_{I - SNS} \qquad Equation 2$$

$${V}_{CM - GND 3} = \frac{2 * {VOUT}_{HV} - Ileak * {R}_{I - SNS}}{2} \approx {V}_{OUT - HV} \qquad Equation 3$$

However, as noted, the difference amplifier 212 avoids the relatively high common mode voltage V_{CM-GND3} by shorting the DUT side of the sensing resistor 252 (e.g., the second node 256) with the high side terminal of the DUT 208, creating two separate grounds, namely, the second ground node 236 and the third ground node 240. Accordingly, with respect to the second ground node 236 and the op-amp 268, the voltage difference across the sensing resistor 252, V_{DIFF-GND2} is defined with Equation 4 and the common mode voltage, V_{CM-GND2} is defined with Equation 5.

$${V}_{DIFF - GND 2} = {I}_{LEAK} * {R}_{I - SNS} \qquad Equation 4$$

$${V}_{CM - GND 2} = ( {I}_{LEAK} * {R}_{I - SNS} ) / 2 \leq 5 V \qquad Equation 5$$

Thus, although the common mode voltage with respect to the third ground node 240 is approximately equal to the voltage at the high side terminal 244, V_{OUT-HV}, the op-amp 268 can be measured with respect to the second ground node 236, such that the common mode voltage of the op-amp 268, V_{CM-GND2} is less than about 5V. This avoids the need to have a relatively high common mode rejection error for components of the difference amplifier 212 (including the op-amp 268). Accordingly, the current sensor circuit 204 provides an isolated current sensing solution that is safely useable with other low voltage circuits, such as other circuits on the tester side.

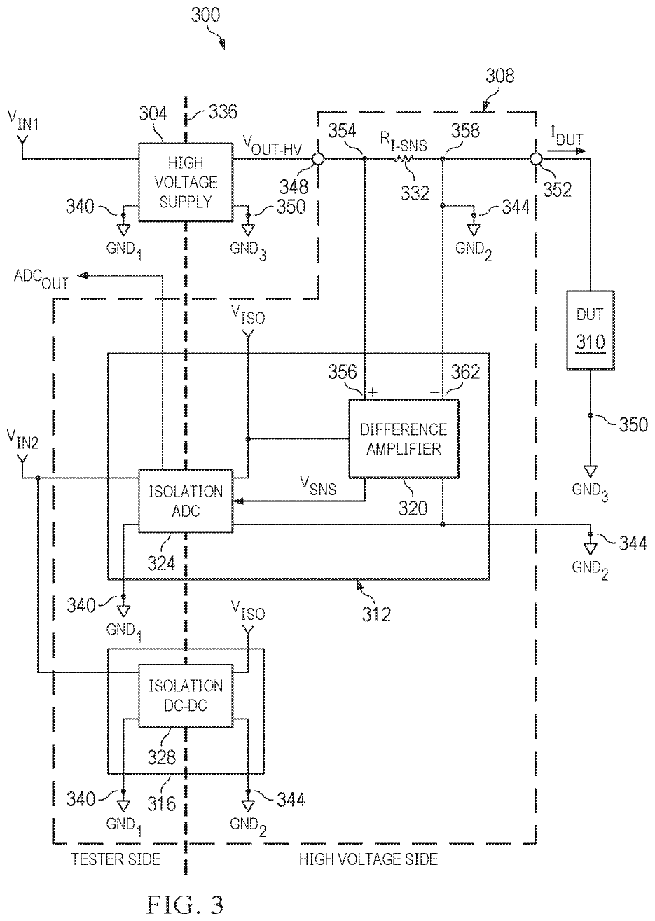

FIG. 3 illustrates an IC package level circuit 300 that is employable to implement the circuit 200 of FIG. 1. The IC package level circuit 300 includes a high voltage supply 304 that is employable to implement the high voltage supply 210 of FIG. 2. The IC package level circuit 300 includes a current sensor circuit 308. The current sensor circuit 308 measures a DUT current, I_{DUT} provided to a DUT 310.

The high voltage supply 304 is implemented on an IC package in some examples. Similarly, in some examples, the DUT 310 is implemented on an IC package. The DUT 310 has an on state, wherein the DUT current, I_{DUT} is at a peak value, and an off-state where the DUT current, I_{DUT} provided to the DUT 310 is a leakage current, I_{LEAK}.

The current sensor circuit 308 includes two IC packages, namely a first IC package 312 and a second IC package 316. The first IC package 312 includes a difference amplifier 320 and an isolation ADC 324 (labeled ISO ADC). The difference amplifier 320 is employable to implement the difference amplifier 212 of FIG. 2 and/or the difference amplifier 108 of FIG. 1. Thus, the difference amplifier 320 includes an op-amp (e.g., the op-amp 268 of FIG. 2) configured in a differential configuration. The second IC package 316 includes an isolation DC-to-DC converter 328 (labeled ISO DC-DC) that is employable to implement the isolation ADC 220 of FIG. 2. The current sensor circuit 308 also includes a sensing resistor 332, R_{I-SNS} that is employable to implement the sensing resistor 252 of FIG. 2, such that the sensing resistor 332 has a resistance of about 10 mΩ.

The IC package level circuit 300 includes a dashed line 336 that denotes a test side and a high voltage side of the IC package level circuit 300, in the same manner as the dashed line 224 of FIG. 2.

In some examples, the high voltage supply 304 is adapted to be coupled to a first input voltage, V_{IN1} and a first ground node 340. In some examples, the first input voltage, V_{IN1} is a DC voltage of about 12 V or less. The isolation ADC 324 and the isolation DC-to-DC converter 328 are adapted to be coupled to a second input voltage, V_{IN2} and to the first ground node 340. The second input voltage, V_{IN2} is a DC voltage of about 3 V to about 12 V (e.g., about 5V) in some examples.

Responsive to the second input voltage, V_{IN2}, the isolation DC-to-DC converter 328 outputs an isolation voltage, V_{ISO} that is about 5 V above a voltage of a second ground node 344, GND₂. The isolation voltage, V_{ISO} is output to a high voltage terminal of the difference amplifier 320 and the isolation ADC 324. A low voltage terminal of the difference amplifier 320 and the isolation ADC 324 are coupled to the second ground node 344. In a similar manner, in response to the first input voltage, VIN₁, the high voltage supply 304 outputs a high voltage output, V_{OUT-HV} to a high side terminal 348 of the current sensor circuit 308. The high voltage output, V_{OUT-HV} is a DC voltage of about 400 V to about 2000 V or more with respect to a third ground node 350 GND₃. Moreover, in some examples, the high voltage supply 304 is not coupled to the first ground node 340 and is coupled to the third ground node 350 such as in situations where the high voltage supply 304 is not an isolated voltage supply.

A low side terminal 352 of the current sensor circuit 308 is coupled to a high side terminal of the DUT 310. The DUT 310 is also coupled to the third ground node 350. The first ground node 340, the second ground node 344 and the third ground node 350 are galvanically isolated from each other. Due to the high input impedance of the first input 356 and the second input 362 of the difference amplifier 320, the sensing resistor 332 is in series with the DUT 310.

The high side terminal 348 is also coupled to a first node 354 of the current sensor circuit 308. The first node 354 of the sensor circuit is coupled to a first input 356 (e.g., a non-inverting input) of the difference amplifier 320 and to the sensing resistor 332. The low side terminal 352 is coupled to a second node 358 of the current sensor circuit 308. This second node 358 is also coupled to the second ground node 344, the sensing resistor 332 and a second input 362 (e.g., an inverting input) of the difference amplifier 320. The first input 356 of the difference amplifier 320 is employable to implement the first input 260 of the difference amplifier 212 of FIG. 2 and the second input 362 is employable to implement the second input 264 of the difference amplifier 212 of FIG. 2.

The IC package level circuit 300 operates in the same manner as the circuit 200 of FIG. 2. Thus, the high voltage supply 304 applies the output voltage, V_{OUT-HV} to the high side terminal 348 of the current sensor circuit 308, which induces the DUT current, I_{DUT} for the DUT 310. The difference amplifier 320 measures a voltage drop across the sensing resistor 332 and outputs a sensing voltage, V_{SNS} that varies as a function of the current across the first ground node 232 and corresponds to the DUT current, I_{DUT} (and varies as a function of the voltage drop across the sensing resistor 332). The sensing voltage, V_{SNS} is output to the isolation ADC 324, which in turns outputs a digital value encoded in a digital signal, ADC_{OUT} that characterizes the sensed voltage, V_{SNS}. Thus, the digital value encoded in the ADC_{OUT} also characterizes the current to the DUT 310.

As noted, the DUT 310 has an on-state, wherein the DUT current, I_{DUT} is presumed to be at a maximum. Also, the DUT 310 has an off-state where the DUT current, I_{DUT} provided to the DUT 310 is equal to the leakage current, I_{LEAK}. Moreover, as noted, the output voltage, V_{OUT-HV} is a DC voltage of about 400 V to about 2000 V or more, including examples where the output voltage, V_{OUT-HV} is about 1500 V. Thus, with respect to the third ground node 350, the common mode voltage, V_{CM-GND3} is about V_{OUT-HV} as demonstrated in Equation 3. However, because the difference amplifier 320 employs the second ground node 344 as a reference and the difference amplifier 320 is powered by the isolation voltage, V_{ISO}, the common mode voltage for the difference amplifier 320 is measured with respect to the voltage at the second ground node 344. Accordingly, as characterized in Equation 5, the common mode voltage with respect to the second ground node 344, V_{CM-GND2} is about 5 V or less. Thus, the difference amplifier 320 can be implemented with a standard op-amp arranged in a differential configuration, as illustrated in FIG. 2.

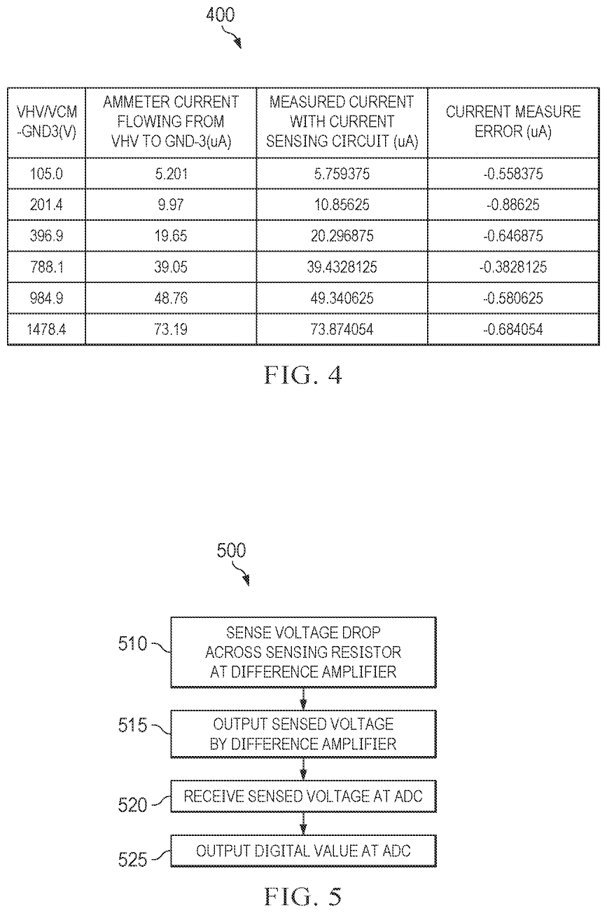

FIG. 4 illustrates a chart 400 with measured results from implemented circuits, such as the circuit 200 of FIG. 2 and/or the IC package level circuit 300 of FIG. 3. The chart 400 includes a ratio of a high voltage output (VHV) and a common mode voltage, VCM for a third ground node (GND3). This value could correspond, for example, to an output voltage of a high voltage supply, such as the high voltage supply 210 of FIG. 2 and/or the high voltage supply 304 of FIG. 3. The chart 400 also plots a measured current, in microamperes (μA) to a DUT, such as the DUT 208 of FIG. 2 and/or the DUT 310 of FIG. 1. The chart includes a measured current in μA for a current sensor circuit, such as the current sensor circuit 100 of FIG. 1, the current sensor circuit 204 of FIG. 2 and/or the current sensor circuit 308 of FIG. 3. The chart 400 further includes a current measure error in μA for the current sensor circuit. As demonstrated, the current measure error is less than 0.9 μA for each recorded output voltage. Thus, the chart 400 demonstrates that the current sensor circuit 100, the current sensor circuit 204 of FIG. 2 and/or the current sensor circuit 308 of FIG. 3 are employable in situations where a high common mode voltage is present.

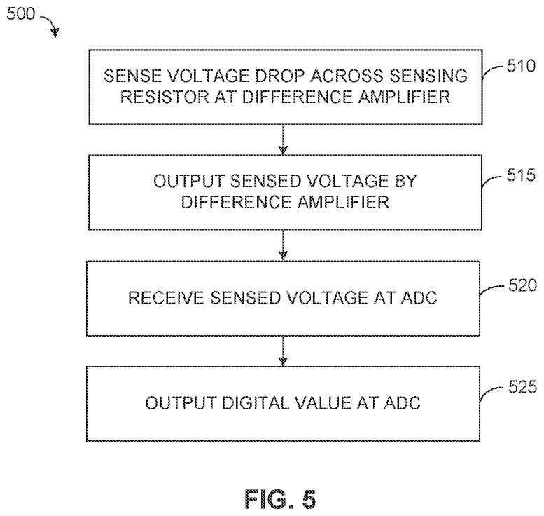

FIG. 5 is a flowchart of an example method 500 of sensing a current. In some examples, the method 500 is implemented with the current sensor circuit 100 of FIG. 1 and/or the current sensor circuit 204 of FIG. 2. At block 510, a difference amplifier (e.g., the difference amplifier 108 of FIG. 1) senses a voltage drop across a sensing resistor (e.g., the sensing resistor 138 of FIG. 1) having a first node (e.g., the first node 143 of FIG. 1) adapted to be coupled to a high side terminal of a voltage supply (e.g., the high side terminal 142 of FIG. 1) and a second node (e.g., the second node 144 of FIG. 1) adapted to be coupled to a high side terminal of a DUT (e.g., the DUT 104 of FIG. 1). A low side terminal of the DUT is coupled to a first ground node (e.g., the third ground node 154 of FIG. 1), and the difference amplifier is coupled to the first node and the second node of the sensing resistor. A low side power terminal of the difference amplifier is coupled to a second ground node (e.g., the second ground node 134 of FIG. 1), and the second ground node is coupled to the high side terminal of the DUT. The first and second ground nodes are galvanically isolated.

At block 515 the difference amplifier outputs a sensed voltage that varies as a function of a current across the sensing resistor in response to receiving an isolated voltage at a high side power terminal (e.g., the high side power terminal 126 of FIG. 1) of the difference amplifier provided from an isolation DC (direct current)-to-DC converter (e.g., the isolation DC-to-DC converter 110 of FIG. 1).

At block 520 an ADC (e.g., the isolation ADC 220 of FIG. 2) receives the sensed voltage from the difference amplifier. At block 525 the isolation ADC outputs a digital value characterizing the current across the sensing resistor.

In this description, unless otherwise stated, “about” preceding a parameter means being within +/−10 percent of that parameter. Modifications are possible in the described embodiments, and other embodiments are possible, within the scope of the claims.

What is claimed is:

1. A current sensor circuit comprising:
a sensing resistor having a first node adapted to be coupled to a high side terminal of a voltage supply and a second node adapted to be coupled to a high side terminal of a DUT (device under test), wherein a low side terminal of the DUT is coupled to a first ground node;
a difference amplifier coupled to the first node and the second node of the sensing resistor, wherein a low side power terminal of the difference amplifier is coupled to a second ground node, and the second ground node is coupled to the high side terminal of the DUT; and
an isolation DC (direct current)-to-DC converter having an output coupled to a high side power terminal of the difference amplifier.

2. The current sensor circuit of claim 1, wherein the first ground node and the second ground node are galvanically isolated.

3. The current sensor circuit of claim 1, wherein the isolation DC-to-DC converter is coupled to a third ground node galvanically isolated from the first ground node and the second ground node.

4. The current sensor circuit of claim 3, further comprising an isolation ADC (analog-to-digital converter) coupled to an output of the difference amplifier.

5. The current sensor circuit of claim 4, wherein the isolation ADC and the difference amplifier are implemented on a first IC (integrated circuit) package and the isolation DC-to-DC converter is implemented on a second IC package.

6. The current sensor circuit of claim 5, wherein the difference amplifier is configured to provide a sensed voltage at the output of the difference amplifier that varies as a function of a current across the sensing resistor.

7. The current sensor circuit of claim 6, wherein the isolation ADC is configured to output a digital value characterizing the current across the sensing resistor.

8. The current sensor circuit of claim 4, wherein the isolation ADC is coupled to the third ground node.

9. The current sensor circuit of claim 2, wherein the difference amplifier is configured to output a sensed voltage that varies as a function of a current across the sensing resistor.

10. The current sensor circuit of claim 2, wherein the voltage supply is configured to supply a voltage of at least 400 volts on the high side terminal of the voltage supply.

11. The current sensor circuit of claim 10, wherein there is a voltage drop of about 5 volts or less between the first node and the second node.

12. The current sensor circuit of claim 2, wherein the voltage supply is configured to supply a voltage of at least 1500 volts on the high side terminal of the voltage supply.

13. A current sensor circuit comprising:
a sensing resistor having a first node adapted to be coupled to a high side terminal of a voltage supply and a second node adapted to be coupled to a high side terminal of a DUT (device under test), wherein a low side terminal of the DUT is coupled to a first ground node;
a difference amplifier coupled to the first node and the second node of the sensing resistor, wherein a low side power terminal of the difference amplifier is coupled to a second ground node that is galvanically isolated from the first ground node, and the second ground node is coupled to the high side terminal of the DUT, the difference amplifier being configured to output a sensed voltage that varies as a function of a current across the sensing resistor; and
an isolation DC (direct current)-to-DC converter configured to provide an isolated voltage to a high side power terminal of the difference amplifier.

14. The current sensor circuit of claim 13, wherein the first ground node and the second ground node have a potential difference.

15. The current sensor circuit of claim 14, wherein the isolation DC-to-DC converter is coupled to a third ground node galvanically isolated from the first ground node and the second ground node.

16. The current sensor circuit of claim 14, further comprising an isolation ADC (analog-to-digital converter) configured to receive the sensed voltage from the difference amplifier and to output a digital value characterizing the current across the sensing resistor.

17. The current sensor circuit of claim 14, wherein the voltage supply is configured to supply a voltage of at least 400 volts on the high side terminal of the voltage supply, and there is a voltage drop of about 5 volts or less between the first node and the second node.

18. A method for sensing current, the method comprising:
sensing, by a difference amplifier, a voltage drop across a sensing resistor having a first node adapted to be coupled to a high side terminal of a voltage supply and a second node adapted to be coupled to a high side terminal of a DUT (device under test), wherein a low side terminal of the DUT is coupled to a first ground node, the difference amplifier is coupled to the first node and the second node of the sensing resistor, and a low side power terminal of the difference amplifier is coupled to a second ground node, and the second ground node is coupled to the high side terminal of the DUT; and
outputting, by the difference amplifier, a sensed voltage that varies as a function of a current across the sensing resistor in response to receiving an isolated voltage at a high side power terminal of the difference amplifier provided from an isolation DC (direct current)-to-DC converter.

19. The method of claim 18, wherein the first ground node and the second ground node are galvanically isolated.

20. The method of claim 19, further comprising:
receiving, at an isolation ADC (analog-to-digital converter) the sensed voltage from the difference amplifier; and
outputting, by the isolation ADC, a digital value characterizing the current across the sensing resistor.
